(19) United States
(12) Patent Application Publication
(10) Pub. No.: US 2018/0374953 A1
(43) Pub. Date: Dec. 27, 2018

(54) METAL OXIDE THIN FILM TRANSISTOR AND METHOD OF MANUFACTURING THE SAME, AND DISPLAY PANEL

(71) Applicant: Shenzhen China Star Optoelectronics Technology Co. Ltd., Shenzhen, Guangdong (CN)

(72) Inventor: Liangfen Zhang, Shenzhen, Guangdong (CN)

(21) Appl. No.: 15/554,597

(22) PCT Filed: Jul. 6, 2017
(86) PCT No.: PCT/CN2017/092066

§ 371 Date: Aug. 30, 2017

(30) Foreign Application Priority Data
Jun. 22, 2017 (CN) 201710482645.7

(51) Int. Cl. H01L 29/786; H01L 29/66; H01L 29/417; H01L 29/423; H01L 23/31

(52) U.S. Cl. CPC H01L 29/7869; H01L 29/66742; G02F 1/1368; H01L 29/42384; H01L 23/3171; H01L 29/41733

(57) ABSTRACT

A metal oxide thin film transistor includes: a substrate; a metal oxide semiconductor layer disposed on the substrate, and including a semiconductor body layer, and a source electrode contact layer and a drain electrode contact layer located at both ends of the semiconductor body layer, respectively; a gate insulating layer disposed on the semiconductor body layer; a gate electrode disposed on the gate insulating layer; a first passivation layer disposed on the gate electrode, the source electrode contact layer and the drain electrode contact layer, and having a first via hole and a second via hole exposing the source electrode contact layer and the drain electrode contact layer respectively; and a source electrode and a drain electrode disposed on the first passivation layer, the source electrode and the drain electrode contacting the source electrode contact layer and the drain electrode contact layer through the first and second via hole, respectively.

### TECHNICAL FIELD

The present invention belongs to the technical field of thin film transistor, particularly, relates to a metal oxide thin film transistor and a method of manufacturing the same, and a display panel.

### BACKGROUND ART

At present, in existing display panels, such as, a liquid crystal display panel or an organic light emitting diode (OLED) display panel, a thin film transistor (TFT) is usually used to serve as a control switch. Generally, the TFTs adopt an amorphous silicon (α-Si) TFT.

However, it is well known that an electron mobility of the α-Si TFT is lower. Compared with the a-Si TFT, the metal oxide TFT has a comparatively higher electron mobility, and may be applied to the technology of transparent display, thus possessing relatively high values in research and development.

### SUMMARY

In order to solve the above problem in the prior art, the present invention aims to provide a metal oxide thin film transistor and a method of manufacturing the same, and a display panel.

According to an aspect of the present invention, there is provided a metal oxide thin film transistor including: a substrate; a metal oxide semiconductor layer disposed on the substrate, the metal oxide semiconductor layer including a semiconductor body layer, and a source electrode contact layer and a drain electrode contact layer located at both ends of the semiconductor body layer, respectively; a gate insulating layer disposed on the semiconductor body layer; a gate electrode disposed on the gate insulating layer; a first passivation layer disposed on the gate electrode, the source electrode contact layer and the drain electrode contact layer, the first passivation layer having a first via hole that exposes the source electrode contact layer and a second via hole that exposes the drain electrode contact layer; and a source electrode and a drain electrode disposed on the first passivation layer, the source electrode filling the first via hole so as to contact the source electrode contact layer, and the drain electrode filling the second via hole so as to contact the drain electrode contact layer.

Alternatively, the semiconductor body layer is made of an amorphous indium-gallium-zinc oxide, and the source electrode contact layer and the drain electrode contact layer are made of an indium-gallium-zinc oxide doped with hydrogen.

Alternatively, the metal oxide thin film transistor further includes: a second passivation layer disposed on the gate electrode, the source electrode contact layer and the drain electrode contact layer, the first passivation layer being disposed on the second passivation layer.

Alternatively, the first passivation layer is made of a silicon oxide, and the second passivation layer is made of a silicon nitride and has a thickness of 5 nm-50 nm.

According to another aspect of the present disclosure, there is also provided a display panel which includes the above metal oxide thin film transistor.

Alternatively, the display panel is a liquid crystal display panel or an organic light emitting diode (OLED) display panel.

According to yet another aspect of the present invention, there is further provided a manufacturing method of a metal oxide thin film transistor including: providing a substrate; forming a metal oxide semiconductor layer on the substrate; forming a gate insulating layer on the metal oxide semiconductor layer; forming a gate electrode on the gate insulating layer; performing patterning process on the gate electrode and the gate insulating layer, so as to remove both ends of the gate electrode and the gate insulating layer, thereby exposing both ends of the metal oxide semiconductor layer; performing ion implantation on the exposed both ends of the metal oxide semiconductor layer so as to form a source electrode contact layer and a drain electrode contact layer, respectively; forming a first passivation layer on the gate electrode, the source electrode contact layer and the drain electrode contact layer; forming, in the first passivation layer, a first via hole that exposes the source electrode contact layer and a second via hole that exposes the drain electrode contact layer; and forming, on the first passivation layer, a source electrode that fills the first via hole so as to contact the source electrode contact layer, and a drain electrode that fills the second via hole so as to contact the drain electrode contact layer.

Alternatively, after the step of “performing ion implantation on the exposed both ends of the metal oxide semiconductor layer so as to form a source electrode contact layer and a drain electrode contact layer, respectively”, and before the step of “forming a first passivation layer on the gate electrode, the source electrode contact layer and the drain electrode contact layer”, the manufacturing method further includes: forming a second passivation layer on the gate electrode, the source electrode contact layer and the drain electrode contact layer; and in the step of “forming, in the first passivation layer, a first via hole that exposes the source electrode contact layer and a second via hole that exposes the drain electrode contact layer”, the first via hole and the second via hole passing through the second passivation layer, respectively.

Alternatively, in the step of “forming a metal oxide semiconductor layer on the substrate”, an amorphous indium-gallium-zinc oxide is used to form the metal oxide semiconductor layer on the substrate.

Alternatively, in the step of “forming a first passivation layer on the gate electrode, the source electrode contact layer and the drain electrode contact layer”, a silicon oxide is used to form the first passivation layer on the gate electrode, the source electrode contact layer and the drain electrode contact layer; and in the step of “forming a second passivation layer on the gate electrode, the source electrode contact layer and the drain electrode contact layer”, a silicon nitride is used to form the second passivation layer on the gate electrode, the source electrode contact layer and the drain electrode contact layer, a thickness of the second passivation layer being 5 nm-50 nm.

The advantageous effects of the present disclosure are: the present disclosure provides a metal oxide thin film transistor which has a comparatively higher electron mobility, and the display panel having the metal oxide thin film transistor has advantages such as high reliability, high luminance, and low power consumption.

### BRIEF DESCRIPTION OF THE DRAWINGS

The foregoing and other aspects, features and advantages of the embodiments of the present invention will become more apparent through the following description in conjunction with the accompanying drawings, in which:

FIG. 1 is a structural diagram of a metal oxide thin film transistor according to an embodiment of the present invention; and

FIGS. 2A-2J are flow charts of a method of manufacturing a metal oxide thin film transistor according to an embodiment of the present invention.

### DETAILED DESCRIPTION OF EXEMPLARY EMBODIMENTS

Hereinafter, embodiments of the present invention will be described in detail by referring to the accompany drawings. However, the present invention can be implemented in numerous different manners and should not be interpreted to be limited to the particular embodiments set forth herein. On the contrary, these embodiments are provided for explaining the principle and practical application of the present invention, thus other skilled in the art can understand various embodiments of the present inverntion and various amendments which are suitable for specific anticipated application.

In the drawings, the thickness of layers and regions are exaggerated for clarity. Same reference numerals designate same components throughout the specification and figures.

It will be understood that when an element such as a layer, film, region, or substrate is referred to as being “on” another element, it can be directly on the another element, or intervening elements may also be present. Alternatively, when an element is referred to as being “directly on” another element, there are no intervening elements present.

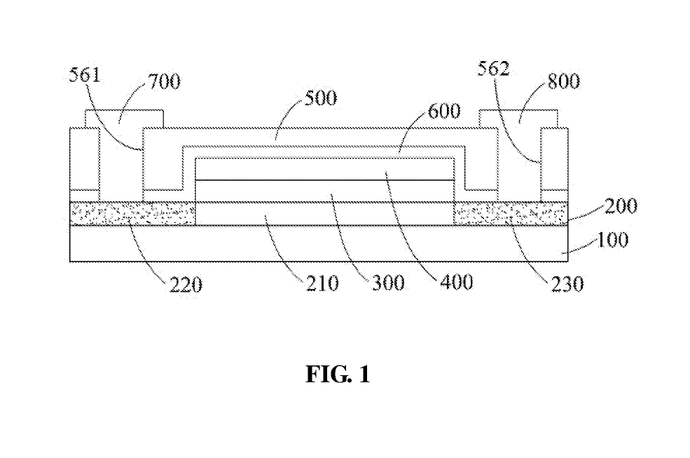

FIG. 1 is a structural diagram of a metal oxide thin film transistor according to an embodiment of the present invention.

Referring to FIG. 1, a metal oxide thin film transistor according to an embodiment of the present invention includes a substrate 100, a metal oxide semiconductor layer 200, a gate insulating layer 300, a gate electrode 400, a first passivation layer 500, a second passivation layer 600, a source electrode 700 and a drain electrode 800.

Specifically, the substrate 100 may be, for example, a glass substrate or a resin substrate.

The metal oxide semiconductor layer 200 is disposed on the substrate 100. The metal oxide semiconductor layer 200 includes a semiconductor body layer 210, and a source electrode contact layer 220 and a drain electrode contact layer 230 located on both ends of the semiconductor body layer 210, respectively. In the present embodiment, preferably, the semiconductor body layer 210 is made of an amorphous indium-gallium-zinc oxide, and the source electrode contact layer 220 and the drain electrode contact layer 230 are made of an amorphous indium-gallium-zinc oxide doped with hydrogen, however, the present invention is not limited thereto.

The gate insulating layer 300 is disposed on the semiconductor body layer 210. Here, the gate insulating layer 300 may be, for example, a structure of SiNₓ/SiOₓ formed on the semiconductor body layer 210, but the present invention is not limited thereto, for example, the gate insulating layer 300 may also be a single-layered struture of SiNₓ or SiOₓ.

The gate electrode 400 is disposed on the gate insulating layer 300. The gate electrode 400 may be, for example, a multi-layered structure of molybdenum-aluminum-molybdenum (MoAlMo) or a titanium-aluminum-titanium (TiAlTi), and may also be a single-layered structure of molybdenum or aluminum.

The second passivation layer 600 is disposed on the gate electrode 400, the source electrode contact layer 220 and the drain electrode contact layer 230. In the present embodiment, preferably, the second passivation layer 600 may be formed of a silicon nitride (e.g., SiNₓ), and has a thickness of 5 nm-50 nm, but the present invention is not limited thereto. As another embodiment of the present invention, the second passivation layer 600 may not exist.

The first passivation layer 500 is disposed on the second passivation layer 600. In the present embodiment, preferably, the first passivation layer 500 is formed of a silicon oxide (e.g., SiOₓ), but the present invention is not limited thereto. When the second passivation layer 600 does not exist, the first passivation layer 500 is directly disposed on the gate electrode 400, the source electrode contact layer 220 and the drain electrode contact layer 230.

Further, the first passivation layer 500 and the second passivation layer 600 have a first via hole 561 that exposes the source electrode contact layer 220 and a second via hole 562 that exposes the drain electrode contact layer 230.

The source electrode 700 and the drain electrode 800 are disposed on the first passivation layer 500, the source electrode 700 fills the first via hole 561 so as to contact the source electrode contact layer 220, and the drain electrode 800 fills the second via hole 562 so as to contact the drain electrode contact layer 230. The source electrode 700 and the drain electrode 800 may adopt a multi-layered structure of molybdenum-aluminum-molybdenum (MoAlMo) or titanium-aluminum-titanium (TiAlTi), and may also be a single-layered structure of molybdenum or aluminum.

The metal oxide thin film transistor according to an embodiment of the present invention may be applied into a display panel, such as a liquid crystal display panel and an OLED display panel. The metal oxide thin film transistor in the embodiment of the present invention has a comparatively higher electron mobility, and the display panel having the metal oxide thin film transistor has advantages such as high reliability, high luminance, low power consumption, and the like.

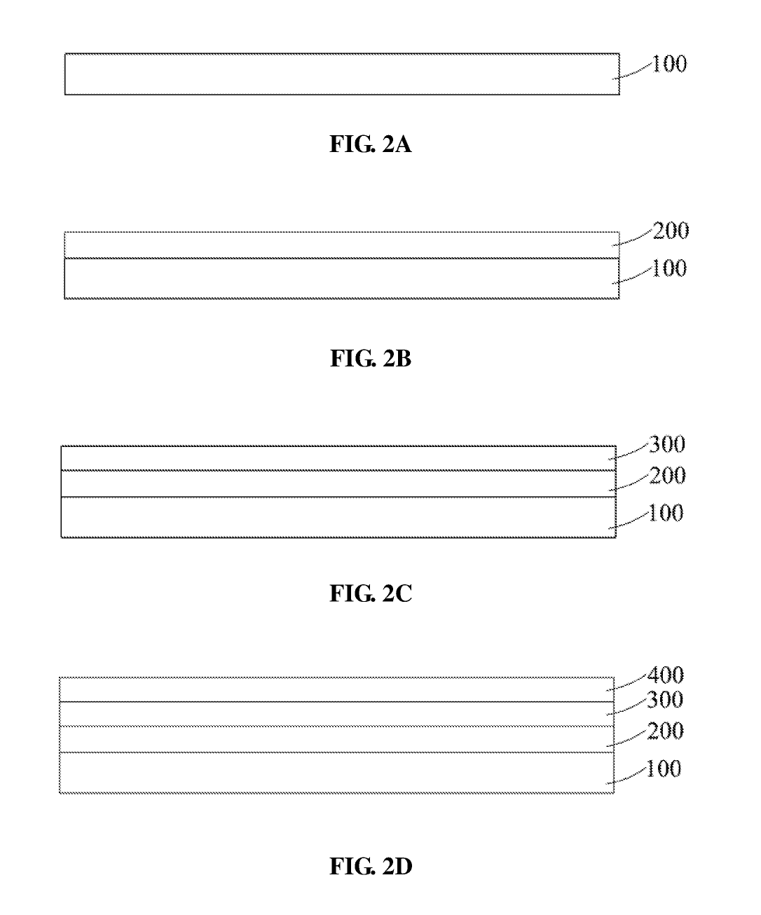

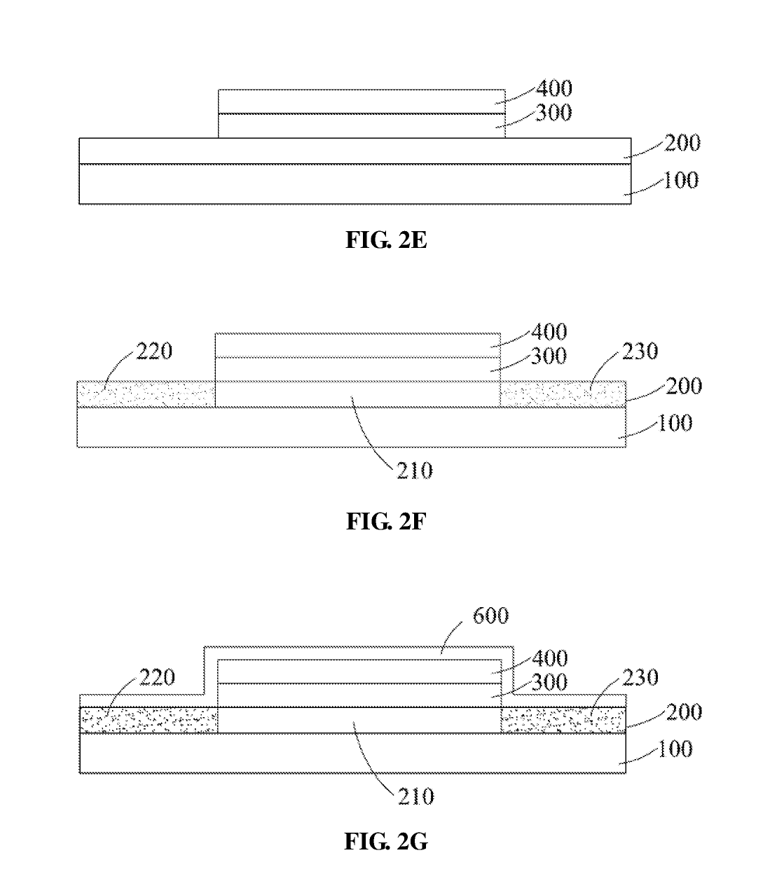

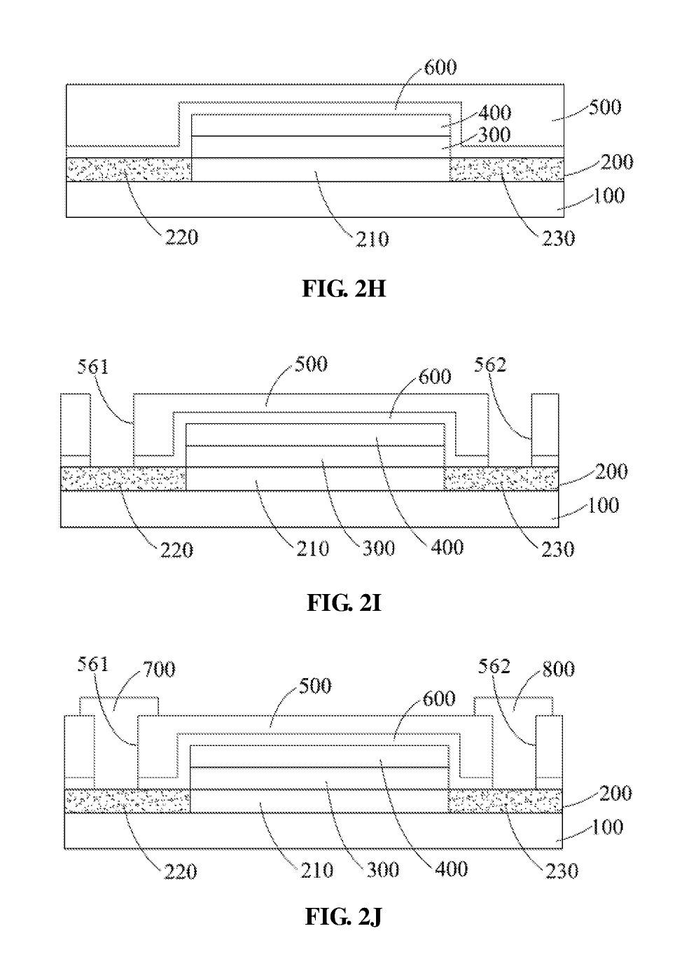

FIGS. 2A-2J are flow charts of the method of manufacturing a metal oxide thin film transistor according to an embodiment of the present invention.

A method of manufacturing a metal oxide thin film transistor according to an embodiment of the present invention includes:

Step 1: referring to FIG. 2A, providing a substrate 100. Here, the substrate 100 may be, for example, a glass substrate or a resin substrate which are insulating and transparent.

Step 2: referring to FIG. 2B, forming a metal oxide semiconductor layer 200 on the substrate 100. In the present embodiment, preferably, the metal oxide semiconductor layer 200 is made of an amorphous indium-gallium-zinc oxide, but the present invention is not limited thereto.

Step 3: referring to FIG. 2C, forming a gate insulating layer 300 on the metal oxide semiconductor layer 200. Here, the gate insulating layer 300 may be, for example, a structure of SiNₓ/SiOₓ formed on the semiconductor body layer 210, but the present invention is not limited thereto, for example, the gate insulating layer 300 may also be a single-layered structure of SiNₓ or SiOₓ.

Step 4: referring to FIG. 2D, forming a gate electrode 400 on the gate insulating layer 300. The gate electrode 400 may be, for example, a multi-layered structure of molybdenum-aluminum-molybdenum (MoAlMo) or a titanium-aluminum-titanium (TiAlTi), and may also be a single-layered structure of molybdenum or aluminum.

Step 5: referring to FIG. 2E, performing patterning process on the gate electrode 400 and the gate insulating layer 300, so as to remove both ends of the gate electrode 400 and the gate insulating layer 300, thereby exposing both ends of the metal oxide semiconductor layer 200.

Step 6: referring to FIG. 2F, performing ion implantation on the exposed both ends of the metal oxide semiconductor layer 200 so as to form a source electrode contact layer 220 and a drain electrode contact layer 230, respectively. The semiconductor body layer 210 is located between the source electrode contact layer 220 and the drain electrode contact layer 230. In addition, hydrogen ion is used to perform ion implantation in this step, but the present invention is not limited thereto.

Step 7: referring to FIG. 2G, forming a second passivation layer 600 on the gate electrode 400, the source electrode contact layer 220 and the drain electrode contact layer 230. Here, the second passivation layer 600 may be formed of a silicon nitride (e.g., SiNₓ), and has a thickness of 5 nm-50 nm, but the present invention is not limited thereto. As another embodiment of the present invention, the second passivation layer 600 may not exist, that is, this step may be omitted.

Step 8: referring to FIG. 2H, forming a first passivation layer 500 on the second passivation layer 600. Here, the first passivation layer 500 is formed of a silicon oxide (e.g., SiOₓ), but the present invention is not limited thereto. When step 7 is omitted, the first passivation layer 500 is formed directly on the gate electrode 400, the source electrode contact layer 220 and the drain electrode contact layer 230.

Step 9: referring to FIG. 21, forming, in the first passivation layer 500 and the second passivation layer 600, a first via hole 561 that exposes the source electrode contact layer 220 and a second via hole 562 that exposes the drain electrode contact layer 230.

Step 10: referring to FIG. 2J, forming, on the first passivation layer 500, a source electrode 700 that fills the first via hole 561 so as to contact the source electrode contact layer 220, and a drain electrode 800 that fills the second via hole 562 so as to contact the drain electrode contact layer 230.

Although the present invention has been illustrated and described with reference to special embodiments, those skilled in the art will understand that: various changes in form and details may be made therein without departing from the spirit and scope of the invention as defined by the claims and their equivalents.

What is claimed is:

1. A metal oxide thin film transistor, comprising:
a substrate;
a metal oxide semiconductor layer disposed on the substrate, the metal oxide semiconductor layer comprising a semiconductor body layer, and a source electrode contact layer and a drain electrode contact layer located at both ends of the semiconductor body layer, respectively;
a gate insulating layer disposed on the semiconductor body layer;
a gate electrode disposed on the gate insulating layer;
a first passivation layer disposed on the gate electrode, the source electrode contact layer and the drain electrode contact layer, the first passivation layer having a first via hole that exposes the source electrode contact layer and a second via hole that exposes the drain electrode contact layer; and
a source electrode and a drain electrode disposed on the first passivation layer, the source electrode filling the first via hole so as to contact the source electrode contact layer, and the drain electrode filling the second via hole so as to contact the drain electrode contact layer.

2. The metal oxide thin film transistor of claim 1, wherein the semiconductor body layer is made of an amorphous indium-gallium-zinc oxide, and the source electrode contact layer and the drain electrode contact layer are made of an indium-gallium-zinc oxide doped with hydrogen.

3. The metal oxide thin film transistor of claim 1, further comprising a second passivation layer disposed on the gate electrode, the source electrode contact layer and the drain electrode contact layer, the first passivation layer being disposed on the second passivation layer.

4. The metal oxide thin film transistor of claim 2, further comprising a second passivation layer disposed on the gate electrode, the source electrode contact layer and the drain electrode contact layer, the first passivation layer being disposed on the second passivation layer.

5. The metal oxide thin film transistor of claim 3, wherein the first passivation layer is made of a silicon oxide, and the second passivation layer is made of a silicon nitride and has a thickness of 5 nm-50 nm.

6. The metal oxide thin film transistor of claim 4, wherein the first passivation layer is made of a silicon oxide, and the second passivation layer is made of a silicon nitride and has a thickness of 5 nm-50 nm.

7. A display panel comprising the metal oxide thin film transistor of claim 1.

8. The display panel of claim 7, wherein, the display panel is a liquid crystal display panel or an organic light emitting diode (OLED) display panel.

9. A manufacturing method of a metal oxide thin film transistor, comprising steps of:
providing a substrate;
forming a metal oxide semiconductor layer on the substrate;
forming a gate insulating layer on the metal oxide semiconductor layer;
forming a gate electrode on the gate insulating layer;
performing a patterning process on the gate electrode and the gate insulating layer, so as to remove both ends of the gate electrode and the gate insulating layer, thereby exposing both ends of the metal oxide semiconductor layer;
performing ion implantation on the exposed both ends of the metal oxide semiconductor layer so as to form a source electrode contact layer and a drain electrode contact layer, respectively;
forming a first passivation layer on the gate electrode, the source electrode contact layer and the drain electrode contact layer;
forming, in the first passivation layer, a first via hole that exposes the source electrode contact layer and a second via hole that exposes the drain electrode contact layer; and
forming, on the first passivation layer, a source electrode that fills the first via hole so as to contact the source electrode contact layer, and a drain electrode that fills the second via hole so as to contact the drain electrode contact layer.

10. The manufacturing method of claim 9, wherein after the step of performing ion implantation on the exposed both ends of the metal oxide semiconductor layer so as to form a source electrode contact layer and a drain electrode contact layer, respectively, and before the step of forming a first passivation layer on the gate electrode, the source electrode contact layer and the drain electrode contact layer, the manufacturing method further comprises: forming a second passivation layer on the gate electrode, the source electrode contact layer and the drain electrode contact layer; and
in the step of forming, in the first passivation layer, a first via hole that exposes the source electrode contact layer and a second via hole that exposes the drain electrode contact layer, the first via hole and the second via hole pass through the second passivation layer, respectively.

11. The manufacturing method of claim 9, wherein in the step of forming a metal oxide semiconductor layer on the substrate, an amorphous indium-gallium-zinc oxide is used to form the metal oxide semiconductor layer on the substrate.

12. The manufacturing method of claim 10, wherein the first passivation layer is made of a silicon oxide, and the second passivation layer is made of a silicon nitride and has a thickness of 5 nm-50 nm.

13. The manufacturing method of claim 10, wherein in the step of forming a first passivation layer on the gate electrode, the source electrode contact layer and the drain electrode contact layer, a silicon oxide is used to form the first passivation layer on the gate electrode, the source electrode contact layer and the drain electrode contact layer; and
in the step of forming a second passivation layer on the gate electrode, the source electrode contact layer and the drain electrode contact layer, a silicon nitride is used to form the second passivation layer on the gate electrode, the source electrode contact layer and the drain electrode contact layer, a thickness of the second passivation layer being 5 nm-50 nm.
